(19) United States
(12) Patent Application Publication
(10) Pub. No.: US 2006/0249795 A1
(43) Pub. Date: Nov. 9, 2006

(54) SEMICONDUCTOR DEVICE AND FABRICATING METHOD THEREOF

(76) Inventors: Neng-Kuo Chen, Hsinchu City (TW); Teng-Chun Tsai, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/908,241

(22) Filed: May 4, 2005

(51) Int. Cl. H01L 29/76

(52) U.S. Cl. 257/371

(57) ABSTRACT

A method of fabricating a semiconductor device is described. A substrate having at least a PMOS and a NMOS is provided first. A dielectric layer which has a first tensile stress is formed on the substrate at least to cover the PMOS and the NMOS. Then, a photo-resist layer is formed on the substrate and the dielectric layer on the PMOS is exposed. An ion implantation is performed to the dielectric layer on the PMOS by using the photo-resist layer as a mask; thus, the portion of the dielectric layer has a second tensile stress. The second tensile stress is less than the first tensile stress. Afterward, the photo-resist layer is removed.

### BACKGROUND OF THE INVENTION

1. Field of the Invention

The present invention relates to a semiconductor device and a fabricating method thereof. More particularly, the present invention relates to a semiconductor device with enhanced carrier mobility and a manufacturing method thereof.

2. Description of Related Art

The metal-oxide semiconductor (MOS) transistor having low electrical consumption is appropriate for the high density integration process. Therefore, a MOS transistor is the most widely applied in basic electronic devices. As the integration of semiconductor devices continues to increase, the dimension of the MOS transistor reduces correspondingly. However, any further size reduction is limited. Therefore, other approaches, for example, by increasing the strain of the transistor's channel to improve the carrier mobility, are currently being evaluated.

For an N-type metal oxide semiconductor transistor, forming a silicon nitride layer having a tensile stress on the N-type MOS transistor is a common method used in increasing the strain of the channel. Further, the increase of the electron mobility is directly proportional to the stress of the silicon nitride film. Accordingly, the stress of the silicon nitride film can be used to control the increase of the electron mobility of the N-type MOS transistor. The higher the stress of the silicon nitride film, the better the electron mobility is resulted.

On the other hand, for a P-type MOS transistor, the higher the tensile stress of the silicon nitride film, the hole mobility decays correspondingly. Therefore, the current goal of the electronic industry is to fabricate a semiconductor device having both types of metal oxide semiconductors, wherein the tensile stress of the silicon nitride film is increased to increase the electron mobility of the N-type MOS and concurrently to reduce the decay of the hole mobility of the P-type MOS.

### SUMMARY OF THE INVENTION

Accordingly, the present invention provides a fabrication method for a semiconductor device, wherein the process is simple and the decay of the hole mobility is also mitigated to increase the operating speed.

The present invention also provides a semiconductor device, wherein the electron mobility of an N-type metal oxide semiconductor (MOS) is enhanced, while the decay of the hole mobility of a P-type metal oxide semiconductor (MOS) is effectively reduced.

The present invention provides a fabrication method of a semiconductor device, wherein the semiconductor device includes at least a P-type MOS transistor and an N-type MOS transistor already formed thereon. A dielectric layer that least covers the P-type MOS transistor and the N-type MOS transistor is then formed over the substrate, wherein the dielectric layer comprises a first tensile stress. Thereafter, a photoresist layer is formed on the substrate. The photoresist layer exposes the dielectric layer above the P-type MOS transistor. Using the photoresist layer as a mask, an ion implantation is performed on the dielectric layer above the P-type MOS transistor to provide the dielectric layer with a second tensile stress, wherein the second tensile stress is smaller than the first tensile stress. The photoresist layer is subsequently removed.

According to an embodiment of the invention for fabricating a semiconductor device, after removing the photoresist layer, the method further includes removing the dielectric layer.

According to an embodiment of the invention for fabricating a semiconductor device, before forming the above-mentioned dielectric layer, a silicide layer is formed on the surface of the source region, the drain region and the gate of the P-type MOS transistor and the N-type MOS transistor, wherein the silicide layer is formed by a self-aligned silicide process.

According to an embodiment of the invention for fabricating a semiconductor device, the above-mentioned dielectric layer is a silicon carbide layer or a silicon nitride layer.

According to an embodiment of the invention for fabricating a semiconductor device, the tensile stress of the above-mentioned silicon nitride layer is about 0.5 to 2.5 GPa, and the silicon nitride layer is formed by plasma enhanced chemical vapor deposition. Further, after forming the silicon nitride layer, a thermal treatment process is performed. The thermal treatment process includes spike anneal, UV curing, e-Beam anneal or laser anneal.

According to an embodiment of the invention for fabricating a semiconductor device, dopants used in the ion implantation process include germanium atoms, wherein the implanted energy is about 50 to 200 KeV and the dopant concentration is about 1×10¹³ ˜1×10¹⁶ atom/cm².

According to an embodiment of the invention for fabricating a semiconductor device, the dopants used in the ion implantation process further includes silicon atoms, argon atoms or xenon atoms.

The present invention provides a semiconductor device which includes a substrate, at least one P-type metal oxide semiconductor (MOS) transistor, at least one N-type metal oxide semiconductor (MOS) transistor and a dielectric layer. The P-type MOS transistor and the N-type MOS transistor are both disposed on the substrate. The dielectric layer is at least disposed above the P-type MOS transistor and the N-type MOS transistor, wherein the tensile stress of the dielectric layer disposed above the N-type MOS transistor is greater than the tensile stress of the dielectric layer disposed above the P-type MOS transistor.

According to the semiconductor device of one embodiment of the present invention, the dielectric layer above the above-mentioned P-type MOS transistor is doped with dopants including but not limited to germanium, silicon, argon or xenon.

After forming the dielectric layer with a high tensile stress, an ion implantation process is further performed on the dielectric layer above the P-type MOS transistor. Not only the process is simple, the stress of the dielectric layer above the P-type MOS transistor also relaxes. As a result, the electron mobility of the N-type MOS transistor is enhanced, while the decay of the hole mobility of the P-type MOS transistor is mitigated concurrently. The operating speed of the device is thereby increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1F are schematic cross-sectional views showing the steps for fabricating a semiconductor device according to an embodiment of the present invention.

FIGS. 2A through 2E are schematic cross-sectional views showing the steps for fabricating a semiconductor device according to another embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

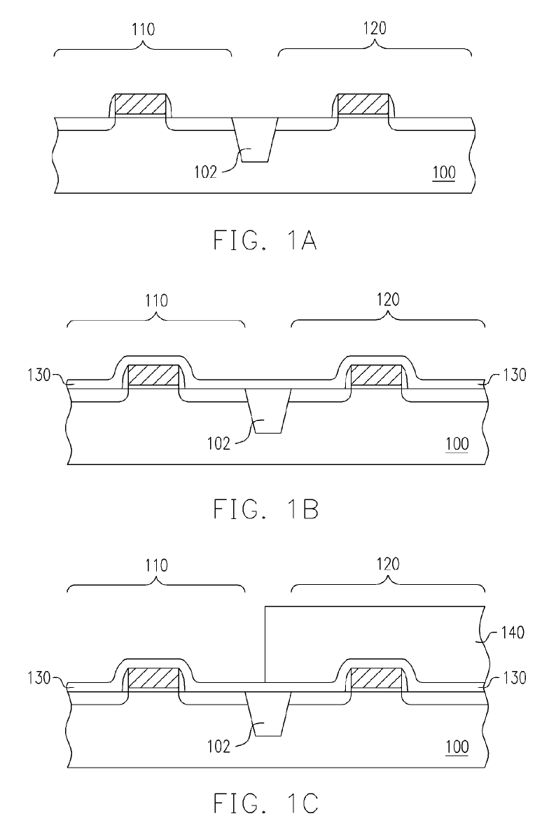

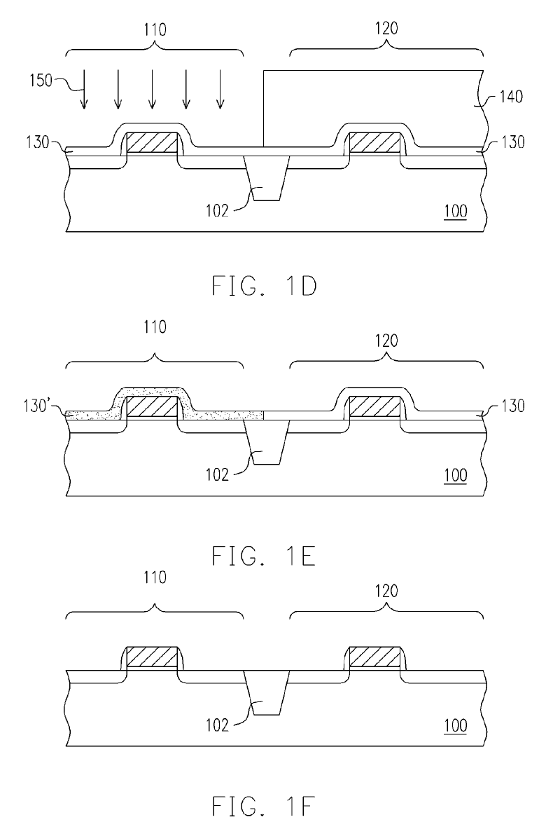

FIGS. 1A through 1F are schematic cross-sectional views showing the steps for fabricating a semiconductor device according to an embodiment of the present invention.

As shown in FIG. 1A, a substrate 100 is provided. The substrate 100 includes a P-type metal oxide semiconductor (MOS) transistor 110 and an N-type metal oxide (MOS) transistor 120 already formed thereon. The P-type metal oxide semiconductor transistor 110 and the N-type metal oxide semiconductor transistor 120 are formed by conventional techniques and will not be further discussed. The two transistors are isolated with an isolation structure 102. The isolation structure 102 is, for example, formed by the shallow isolation trench structure process, the local oxidation (LOCOS) process or other appropriate processes.

As shown in FIG. 1B, a dielectric layer 130 is formed on the substrate 100, covering the P-type MOS transistor 110 and N-type MOS transistor 120, wherein the dielectric layer 130 has a tensile stress. The dielectric layer 130 is, for example, silicon carbide (SiC), or silicon nitride or other material that possesses a tensile stress. The silicon nitride film is formed by, for example, plasma enhanced chemical vapor deposition, using high radio frequency energy to control the process parameters, such as the ratio of the reacting gases, to form a silicon nitride film having a tensile stress of about 0.5 to 2.5 Gpa.

The formation of the silicon nitride film further includes performing a thermal treatment after the silicon nitride film is deposited to adjust the tensile stress to about 0.5 to 2.5 GPa. The thermal treatment process can be conducted after the forming of the silicon nitride film. The thermal treatment process is conducted using but not limited to the following methods: spike anneal, UV curing, E-beam anneal or laser anneal.

Continuing to FIG. 1C, a photoresist layer 140 is formed on the substrate 100, wherein the photoresist layer 140 exposes the dielectric layer 130 above the P-type MOS transistor 110. The photoresist layer 140 is, for example, a positive photoresist. The photoresist layer 140 is formed by spin coating a photoresist material layer (not shown) on the dielectric layer 130, followed by applying photolithography to pattern the photoresist material layer to form the photoresist layer 140.

As shown in FIG. 1D, using the photoresist layer 140 as a mask, an ion implantation process 150 is performed on the dielectric layer 130 above the P-type MOS transistor 110. The dopants used in the ion implantation process 150 include, but not limited to, silicon atoms, argon atoms or xenon atoms. Further, germanium atoms can also be used as dopants for the ion implantation process 150. Implanting germanium atoms include controlling the implanting energy to about 50 to 200 KeV and the dosage to about 1×10¹³ to 1×10¹⁶ atoms/cm².

Referring to FIG. 1E, the dielectric layer 130 above the P-type MOS transistor 110, after being subjected to the ion implantation process 150, becomes a dielectric layer 130′ possessing a second tensile stress, wherein the second tensile stress of the dielectric layer 130′ is less than the first tensile stress of the dielectric layer 130. Thereafter, the photoresist layer 140 is removed, for example, by wet etching or dry etching. In one embodiment of the invention, as shown in FIG. 1F, after the photoresist layer 140 is removed, the dielectric layer 130 and the dielectric layer 130′ are further removed in order to perform the subsequent process, for example, the self-aligned silicide process.

The following disclosure is directed to the structure obtained by the above-mentioned process. Referring to FIG. 1E, the semiconductor device includes the substrate 100, the P-type metal oxide semiconductor transistor 110, the N-type metal oxide semiconductor transistor 120, the dielectric layer 130 and the dielectric layer 130′. The two transistors are isolated with the isolation structure 102. The P-type MOS transistor 110 and the N-type MOS transistor 120 are disposed on the substrate 100. The dielectric layer 130′ is disposed above the P-type MOS transistor 110, while the dielectric layer 130 is disposed above the N-type MOS transistor 120, wherein the tensile stress of the dielectric layer 130 above the N-type MOS transistor 120 is greater than that of the dielectric layer 130′ above the P-type MOS transistor 110. Further, the dielectric layer 103′ is doped with germanium, silicon, argon or xenon types of dopants.

The fabrication of the above semiconductor device includes performing an ion implantation process 150 on the dielectric layer 130 above the P-type MOS transistor 110 after the formation of the dielectric layer 130 above both the P-type MOS transistor 110 and the N-type MOS transistor 120. The process is simple and easy. Moreover, the tensile stress of the dielectric layer 130′ above the P-type MOS transistor 110 is reduced. As a result, the decay of the hole mobility of the P-type MOS transistor 110 due to the relaxation of the tensile stress of the dielectric layer 130.

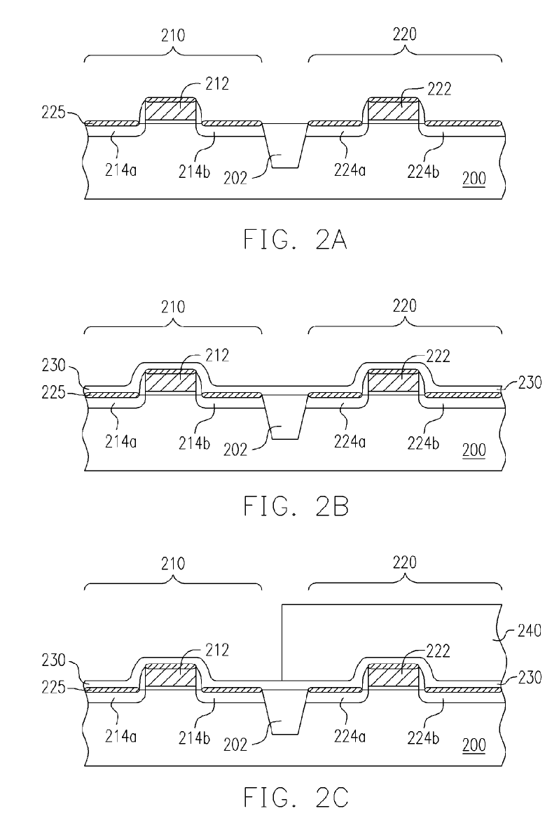

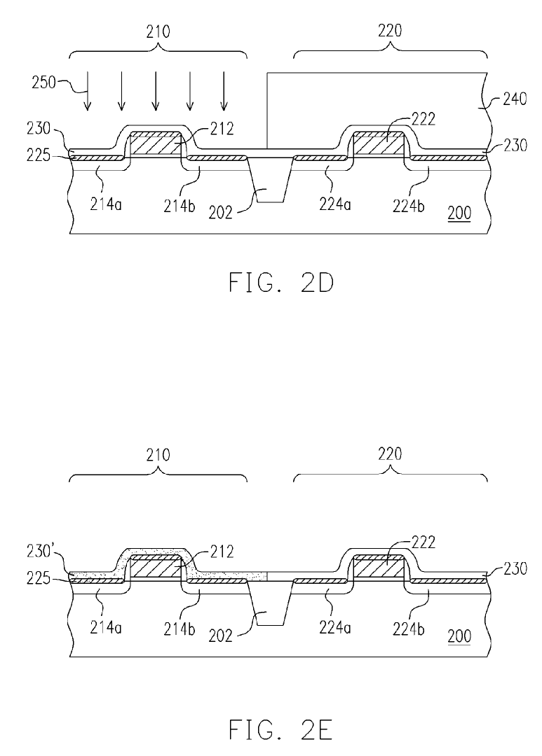

FIGS. 2A through 2E are schematic cross-sectional views showing the steps for fabricating a semiconductor device according to another embodiment of the present invention.

Referring to FIG. 2A, a substrate 200 having a P-type MOS transistor and an N-type MOS transistor alredy formed thereon is provided. The P-type MOS transistor and the N-type MOS transistor are formed with skills well known in the art. The two transistors are isolated from each other with an isolation structure 202, wherein the isolation structure 202 is formed with, for example, the shallow trench isolation structure process, the local oxidation (LOCOS) process or other appropriate process.

Further, the surfaces of the source region 214a, the drain region 214b and the gate 212 of the P-type MOS transistor 210 and the surfaces of the source region 224a, the drain region 224b and the gate 222 of the N-type MOS transistor 210 are formed with a silicide layer 225. The silicide layer 225 is formed by a self-aligned silicide process.

Continuing to FIG. 2B, a dielectric layer 230 is formed above the substrate 200 to cover at least the p-type MOS transistor 210 and the N-type MOS transistor 220, and the dielectric layer 230 has a first tensile stress. The material of the dielectric layer 230 includes silicon carbide, silicon nitride or other appropriate materials. When the dielectric layer 230 is a silicon nitride film, the dielectric layer 230 is formed by, for example, plasma enhance chemical vapor deposition. By using high radio frequency energy and controlling the reaction gas ratio of silicon carbide to nitrogen, a silicon nitride film with a tensile stress of about 0.5 to 2.5 GPa is formed.

Further, the formation of the silicon nitride film further includes a thermal treatment step to control the tensile stress to about 0.5 to 2.5 Gpa after the deposition of the silicon nitride film. The thermal treatment step is conducted using, but not limited to, spike anneal, UV curing, E-beam anneal or laser anneal type of techniques.

Continuing to FIG. 2C, a photoresist layer 240 that exposes the dielectric layer 230 above the P-type MOS transistor 210 is formed on the substrate 200. The photoresist layer 240 is, for example, a positive photoresist. The photoresist layer 240 is formed by spin-coating a photoresist material layer over the dielectric layer 230, followed by using an exposure and a development process to pattern the photoresist material layer to form the photoresist layer 240.

Referring to FIG. 2D, using the photoresist layer 240 as a mask, an ion implantation process 250 is performed on the dielectric layer 230 above the P-type MOS transistor 210. The implanted dopants include but not limited to silicon atoms, argon atoms or xenon atoms. Moreover, germanium atoms can also be used as dopants. Implanting geranium atoms includes, for example, controlling the implanting energy to about 50 to 200 KeV to implant the dopants with a concentration of about 1×10¹³ to 1×10¹⁶ atoms/cm².

As shown in FIG. 2E, after the ion implantation process 250 is performed on the dielectric layer 230 above the P-type MOS transistor 220, the dielectric layer 230′ with a second tensile stress is resulted. The second tensile stress of the dielectric layer 230′ is less than the first tensile stress of the dielectric layer 230. The photoresist layer 240 is subsequently removed, for example, by using the wet etching method or the dry etching method.

The semiconductor device, as shown in FIG. 2, formed according to the above-mentioned fabrication method is different in structure from that formed in the first embodiment. For example, the semiconductor device formed according to the second embodiment further includes a metal silicide layer disposed on the surfaces of the source region, the drain region and the gate structure of the P-type MOS transistor 210 and the N-type MOS transistor 220.

According to the fabrication method of the second embodiment, an ion implantation process 250 is performed on the dielectric layer 230 above the P-type MOS transistor 210 after the formation of the dielectric layer 230 above both the P-type MOS transistor 210 and the N-type MOS transistor 220. Not only the process is simple and easy, the tensile stress of the dielectric layer 230′ above the P-type MOS transistor is effectively reduced. As a result, the decay of hole mobility of the P-type MOS transistor due to the formation of the dielectric layer 230 with a high tensile stress is obviated. Further, if the dielectric layer 230 is a silicon nitride film layer, the dielectric layer 230 formed above the silicide layer 226 can also serve as a contact etch silicon layer during the forming of a contact window. Affected by the stress of this film layer, the carrier mobility is also enhanced.

Accordingly, after forming the dielectric layer with a tensile stress above the P-type MOS transistor and the N-type MOS transistor, an ion implantation process is performed on the dielectric layer above the P-type MOS transistor. The process is simple and the tensile stress of the dielectric layer above the P-type MOS transistor can be reduced. Therefore, the decay of the hole mobility of the P-type MOS transistor is mitigated. With the device structure provided by the present invention, the electron mobility of the N-type MOS transistor is increased while the decay of the hole mobility of the P-type MOS transistor is decreased to improve the operating speed of the device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1-14. (canceled)

15. A semiconductor device, comprising:
a substrate;
at least a P-type metal oxide semiconductor (MOS) transistor and an N-type metal oxide semiconductor (MOS) transistor disposed on the substrate; and
a dielectric layer at least disposed above the P-type MOS transistor and the N-type MOS transistor, wherein the dielectric layer above the P-type MOS transistor is doped with a dopant and the dielectric layer above the N-type MOS transistor is not doped with the dopant such that a tensile stress of the dielectric layer positioned above the N-type MOS transistor is greater than a tensile stress of the dielectric layer positioned above the P-type MOS transistor.

16. The semiconductor device of claim 15 further comprises a silicide layer disposed above source regions, drain regions and gates of the P-type MOS transistor and the N-type MOS transistor.

17. The semiconductor device of claim 15, wherein the dielectric layer comprises silicon nitride.

18. The semiconductor device of claim 15, wherein the dielectric layer comprises silicon carbide.

19. The method of claim 15, wherein the dielectric layer disposed above the P-type MOS transistor is doped with germanium.

20. The semiconductor device of claim 15, wherein the dielectric layer disposed above the P-type MOS transistor is doped with silicon, argon or xenon.
